(19) United States
(12) Patent Application Publication
(10) Pub. No.: US 2024/0104272 A1
(43) Pub. Date: Mar. 28, 2024

(54) FREE MOTION HEADFORM IMPACT PERFORMANCE PREDICTION DEVICE AND A METHOD USING ARTIFICIAL INTELLIGENCE

(71) Applicants: HYUNDAI MOTOR COMPANY, Seoul (KR); KIA CORPORATION, Seoul (KR); SOONCHUNHYANG UNIVERSITY INDUSTRY ACADEMY COOPERATION FOUNDATION, Asan-si (KR)

(72) Inventors: Ji Seob Park, Incheon (KR); Ji Ah Kim, Seoul (KR); Min Ho Cho, Suwon-si (KR); Hae Young Jeon, Seongnam-si (KR); Seong Keun Park, Asan-si (KR); Ji Eun Lee, Asan-si (KR); Si Hyeon Yu, Asan-si (KR)

(73) Assignees: HYUNDAI MOTOR COMPANY, Seoul (KR); KIA CORPORATION, Seoul (KR); SOONCHUNHYANG UNIVERSITY INDUSTRY ACADEMY COOPERATION FOUNDATION, Asan-si (KR)

(21) Appl. No.: 18/201,809

(22) Filed: May 25, 2023

(30) Foreign Application Priority Data
Sep. 23, 2022 (KR) 10-2022-0120769

(51) Int. Cl. G06F 30/27; G06F 30/15

(52) U.S. Cl. CPC G06F 30/27; G06F 30/15

(57) ABSTRACT

A free motion headform (FMH) impact performance prediction device using artificial intelligence includes a data processing processor configured to generate an image by extracting a pre-processed test target image, generated by pre-processing test target design data, using a pre-trained model and generate a pre-processed test target distance value by pre-processing the test target design data. The FMH input performance prediction device also includes a machine learning processor configured to concatenate the image generated by extraction on the basis of the pre-trained model and the pre-processed test target distance value and to predict impact performance using a neural network in which parameters are updated by learning based on an image obtained by pre-processing existing design data and existing impact amount data corresponding to the existing design data. The FMH input performance prediction device further includes an output processor configured to output a value learned by the machine learning processor.

### CROSS-REFERENCE TO RELATED APPLICATION

This application claims the benefit of and priority to Korean Patent Application No. 10-2022-0120769, filed on Sep. 23, 2022, the entire contents of which are incorporated herein by reference.

### FIELD OF TECHNOLOGY

The present disclosure relates to a free motion headform (FMH) impact performance prediction device and a method using artificial intelligence.

### BACKGROUND

A free motion headform (FMH) impact performance test is typically performed according to a Federal Motor Vehicle Safety Standard (FMVSS) No. 201. FMVSS 201 establishes regulations for occupant protection impact performance for interior parts of an inner upper portion of a vehicle. The interior parts targeted by the FMH impact performance test include a headlining assembly and a pillar trim in the vehicle. The headlining assembly includes an additional impact absorbing member inserted thereto to mainly improve impact absorbing performance. The pillar trim mainly uses an impact absorption method using the existing touch rib for reinforcing strength. These interior parts serve to improve an aesthetic appearance of a vehicle interior space and perform various functions. Examples of the various functions of the interior parts include lighting of a vehicle interior, installation of a seat belt height adjustment device and an assist handle, installation of a curtain airbag, and provision of convenience facilities. Further, the interior parts play important roles as finishing materials for the vehicle interior.

Recently, according to the trend of a slim design of vehicle exterior styling, there is a need for a design method of satisfying a design criteria of head clearance and securing a minimum impact absorbing space inside the headlining to satisfy impact safety regulations. Examples of considerations in designing an FMH impact absorption structure include improvement in rigidity of a vehicle body according to a roof strength test in preparation for a vehicle rollover accident, improvement in rigidity of a pillar part for improving side impact performance, reinforcement of an axial load support structure of an assist handle fixing part, and reinforcement of a structure of an upper end portion of a pillar trim for preventing breakage and separation of the pillar trim which occurs when a curtain airbag is deployed. This increase in rigidity results in an increase in rigidity of the vehicle body and the structure and a decrease in impact absorbing performance.

In addition to these design standards in various fields, there are problems with performance fluctuation and deviation generation for each FMH striking position due to a difficulty occurring in the process of promoting FMH performance. The performance fluctuation mainly occurs due to a limitation of thickness application in manufacturing of an injection-type shock absorber made of a polypropylene-based material, and a head injury criteria for dummy HIC(d) calculation method is sensitive to a deceleration change. This is for a deviation according to the striking position because the FMH impact performance test includes most of possibilities which can occur in vehicle collision accidents and rollover accidents so that the striking position corresponds to almost the entire interior material area and is variously applied according to approach angle striking position of the headform. In the process of promoting the FMH impact performance of the headlining, it is necessary to insert an impact absorber having appropriate strength according to a cross section and component parts based on the striking position.

Examples of the structure used as the FMH shock absorbing member include a foam molding structure, a vacuum molding conical structure, a grid-type injection rib structure, and an aluminum thin plate overlapping structure. Generally, most of the above structures are structures for absorbing impact energy through sequential bending deformation. The impact absorbing performance depends on a magnitude and uniformity of absorbed energy per unit volume of the impact absorbing structure. However, it is difficult to easily confirm and reflect the performance of the impact absorbing structure to the design due to a difference in rigidity according to a vehicle type and a difference according to a striking position, and it takes a lot of time and resources to review and improve the performance of the FMH impact absorbers in the overall vehicle structure.

In order to improve safety performance of the vehicle, automobile manufacturers design the vehicle, manufacture an actual vehicle to check whether a target safety level is achieved, conduct the above various tests, and repeat the procedure of reflecting the test results into the vehicle design. This process is costly and takes a lot of time, and as the same test is repeatedly performed, a lot of man-hours are incurred. In addition, in an initial development or pre-development stage in which a vehicle for an actual test cannot be manufactured, safety performance of the vehicle associated with new design information cannot be tested, and thus the safety performance of the developed vehicle cannot be confirmed.

The statements in this section merely provide background information related to the present disclosure and may not constitute prior art.

### SUMMARY

The present disclosure has been made in an effort to solve the above-described problems associated with prior art.

In one aspect, the present disclosure provides a free motion headform (FMH) impact performance prediction device and a method using artificial intelligence capable of reducing a prediction error and costs/man-hours associated with performance testing, through deep learning analysis, when compared to the existing analysis-based performance prediction process.

In another aspect, the present disclosure provides an FMH impact performance prediction device and a method using artificial intelligence capable of predicting occupant impact performance of a vehicle when an analysis model in an initial stage of a vehicle design and an actual vehicle test are not possible.

Objectives of the present disclosure are not limited to the above-described objectives, and other objectives of the present disclosure, which are not mentioned, are set forth in part in the description which follows and, in part, should be apparent from the description, or may be learned by practice of the presented embodiments of the disclosure. Further, the objectives of the present disclosure can be implemented by means described in the appended claims and a combination thereof.

In an embodiment, an FMH impact performance prediction device using artificial intelligence includes a data processing processor configured to generate an image by extracting a pre-processed test target image, generated by pre-processing test target design data, using a pre-trained model and generate a pre-processed test target distance value by pre-processing the test target design data. FMH impact performance prediction device also includes a machine learning processor configured to concatenate i) the image generated by extraction using the pre-trained model and ii) the pre-processed test target distance value, and predict impact performance using a neural network in which parameters are updated by learning based on i) an image obtained by pre-processing existing design data and ii) existing impact amount data corresponding to the existing design data FMH impact performance prediction device further includes an output processor configured to output a value predicted by the machine learning processor.

In an aspect, the pre-trained model may comprise a DenseNet201 model, and the image generated by extraction using the pre-trained model is generated further using global average pooling (GAP).

In an aspect, the existing design data may be a design image of a cross-section of a vehicle, and generating the image may include cropping an outer portion of the image of the existing design data.

In an aspect, the existing design data may include material information of a headlining. The material information may be information in which a material of the headlining is reflected in the design image by at least one of a color, a chroma, a brightness, a solid line, and a dotted line.

In an aspect, the image obtained by pre-processing existing design data may be obtained by cropping an outer portion of the design image corresponding to the existing design data by a same size on the basis of a headform.

In an aspect, the image obtained by pre-processing existing design data may be an image in which a blank image region excluding the design image is enlarged with respect to the existing design data.

In an aspect, the impact performance prediction may be learned by a multi-layer perceptron (MLP) learning model or a convolution neural network (CNN) learning model.

In another embodiment, a method of predicting free motion headform (FMH) impact performance using artificial intelligence includes generating an image by extracting a pre-processed test target image, generated by pre-processing test target design data, using a pre-trained model, and generating a pre-processed test target distance value by pre-processing the test target design data. The method also includes concatenating i) the image generated by extraction using the pre-trained model and ii) the pre-processed test target distance value. The method further includes predicting impact performance using a neural network in which parameters are updated by learning based on i) an image obtained by preprocessing existing design data and ii) existing impact amount data corresponding to the existing design data. The method additionally includes outputting a predicted impact performance value.

In an aspect, the pre-trained model may comprise a DenseNet201 model, and the image generated by extraction using the pre-trained model may be generated further using global average pooling (GAP).

In an aspect, the existing design data may comprise a design image of a cross-section of a vehicle, and generating the image include cropping an outer portion of the image of the existing design data.

In an aspect, the existing design data may include material information of a headlining. The material information may be information in which a material of the headlining is reflected into the design image by at least one among a color, a chroma, a brightness, a solid line, and a dotted line.

In an aspect, the image obtained by pre-processing existing design data may be obtained by cropping an outer portion of the design image corresponding to the existing design data by a same size on the basis of a headform.

In an aspect, the image obtained by pre-processing existing design data may be an image in which a blank image region excluding the design image is enlarged with respect to the existing design data.

In an aspect, the impact performance prediction may be learned by a multi-layer perceptron (MLP) learning model or a convolution neural network (CNN) learning model.

As used herein, the term “vehicle” or “vehicular” or other similar term is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

### BRIEF DESCRIPTION OF THE DRAWINGS

The above and other objects, features and advantages of the present disclosure may be more apparent from the following detailed description of exemplary embodiment taken in conjunction with the accompanying drawings, given by way of non-limiting illustration, in which:

FIG. 1 is an overview diagram illustrating an example process that may be performed by a free motion headform (FMH) impact performance prediction device using artificial intelligence, according to an embodiment of the present disclosure;

FIG. 2 is a control block diagram illustrating an FMH impact performance prediction device using artificial intelligence, according to an embodiment of the present disclosure;

FIGS. 3 and 4 are diagrams for describing pre-processing performed by an FMH impact performance prediction device using artificial intelligence, according to an embodiment of the present disclosure;

FIG. 5 is a diagram for describing states before and after global average pooling (GAP) performed by an FMH impact performance prediction device using artificial intelligence, according to an embodiment of the present disclosure;

FIG. 6 is a diagram for describing a concatenation method performed by an FMH impact performance prediction device using artificial intelligence, according to an embodiment of the present disclosure; and

FIG. 7 is a flowchart of an FMH impact performance prediction method using artificial intelligence, according to an embodiment of the present disclosure.

It should be understood that the appended drawings are not necessarily to scale, presenting a somewhat simplified representation of various preferred features illustrative of the basic principles of the present disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter, embodiments of the present disclosure are described in more detail with reference to the accompanying drawings. The embodiments of the present disclosure can be modified in various forms, and the scope of the present disclosure should not be construed as being limited to the following embodiments. These embodiments are provided to more fully describe the present disclosure to those skilled in the art.

Further, the term “ . . . processor,” or the like used herein means a unit for processing at least one function or operation, and this unit may be implemented by software or hardware.

In steps described herein, reference numerals are used for convenience of description, and these reference numerals do not describe the order of the steps, and the steps may be differently performed from the described order unless clearly specified in the context.

When a part described in the present specification is referred to as being “connected” to other part, it includes not only a direct connection but also an indirect connection, and the indirect connection includes a connection through a wireless communication network.

In describing the components of the embodiment according to the present disclosure, terms such as first, second, “A”, “B”, (a), (b), and the like may be used. These terms are only used to distinguish one element from another element, but do not limit the corresponding elements irrespective of the order or priority of the corresponding elements.

When a component, device, element, or the like of the present disclosure is described as having a purpose or performing an operation, function, or the like, the component, device, or element should be considered herein as being “configured to” meet that purpose or perform that operation or function.

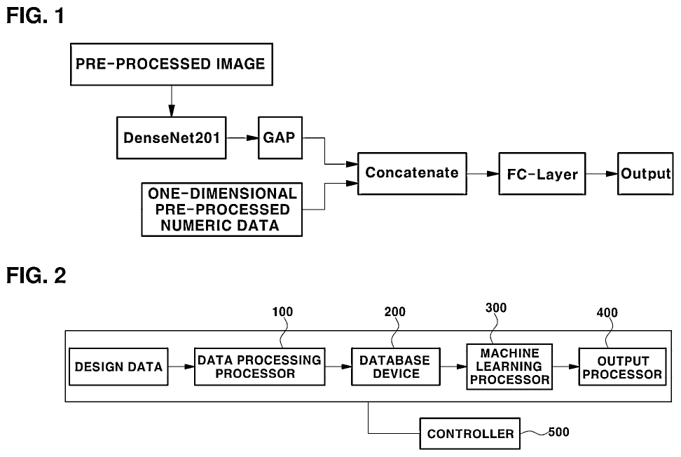

FIG. 1 is an overview diagram illustrating an example process performed by a free motion headform (FMH) impact performance prediction device using artificial intelligence, according to one embodiment of the present disclosure. FIG. 2 is a control block diagram illustrating an FMH impact performance prediction device using artificial intelligence, according to an embodiment of the present disclosure;

Referring to FIGS. 1 and 2, an FMH impact performance prediction device using artificial intelligence according to an embodiment of the present disclosure may include a data processing processor 100, a machine learning processor 300, and an output processor 400.

The data processing processor 100 may generate an image by extracting a pre-processed test target image, generated by pre-processing test target design data, using a pre-trained model. The data processing processor 100 may also generate a pre-processed test target distance value by pre-processing the test target design data.

The data processing processor 100 may receive design data and perform a pre-processing operation on the received design data. The design data may include information on a design produced by a computer-aided design program for designing and developing a three-dimensional (3D) object. As an example, the design data may be design information produced by using computer aided three dimensional interactive application (CATIA). The data processing processor 100 may use segmented data to efficiently perform pre-processing operations.

The data processing processor 100 may generate two types of data input to the machine learning processor 300. First data input to the machine learning processor 300 may be the image generated by extraction using the pre-trained model. Second data input to the machine learning processor 300 may be the pre-processed test target distance value. One-dimensional pre-processed numeric data shown in FIG. 1 may be the second data with a distance value of 1×1.

As shown in FIG. 1, the FMH impact performance prediction device using artificial intelligence according to an embodiment of the present disclosure may be configured to receive the first data and the second data, perform machine learning, and output a head injury criterion (HIC) value. The HIC value may be a value expressing an amount of impact applied to a head as a constant value.

The pre-trained model may comprise a DenseNet201 model. The DenseNet201 model may comprise a convolutional neural network consisting of 201 layers. The image generated by extraction using the pre-trained model may be generated further using global average pooling (GAP).

The machine learning processor 300 may be configured to concatenate the image generated by extraction using the pre-trained model with the pre-processed test target distance value, and to predict impact performance using a neural network in which parameters are updated by learning based on an image obtained by pre-processing existing design data and existing impact amount data corresponding to the existing design data. In an embodiment, the machine learning processor 300 may be configured to receive and concatenate the first data and the second data and predict the HIC value by providing the concatenated first data and second data to a fully-connected (FC) layer.

In an example, data in which the first data and the second data are concatenated may be used as an input of the FC layer. Hereinafter, the first data, according to an embodiment, is described in more detail.

The first data may be the image generated by extraction using the pre-trained model. After the pre-processed test target image is extracted using the pre-trained model, a 7×7 size feature map may be generated and then converted by GAP to a 1×1 size feature map. The first data may thus be the 1×1 size feature map.

Because a neural network performs machine learning to train a neural structure capable of performing deep learning, it is possible to improve reliability of learning as a weight and a bias, that correspond to a configuration of the neural network, are continuously changed.

Machine learning may improve an inference result of the neural network by continuously updating a weight, a bias, and an activation function, which are included in the neural network, based on the pre-processed test target image and the pre-processed test target distance value. The neural network may be stored in a storage medium, such as a database device 200, in the form of a computer program. Hereinafter, an operation performed by the neural network in the form of coding of the computer program is described, but the neural network is not necessarily limited to a stored computer program.

In an embodiment, the neural network includes a convolution neural network (CNN) for generating a feature map output by convolving the pre-processed test target image with the pre-processed test target distance value and for inputting the feature map to the neural network, but the present disclosure is not limited thereto, and other deep learning algorithms, including a recurrent neural network (RNN), may be performed. In other words, there is no limit to a type of the neural network that may be used.

Impact performance prediction of the machine learning processor 300 may be performed by representing an amount of impact applied to a driver's head that collides with the headlining as a constant. A value of the amount of impact applied to the driver's head that collides with the headlining may be the HIC value. The impact performance prediction may be learned by a multi-layer perceptron (MLP) learning model or a CNN learning model.

The database device 200 may store input data, generated by the data processing processor 100, to be used by the machine learning processor 300. As an example, the database device 200 may store the first data and the second data. The database device 200 may include a high-speed random access memory (RAM), a magnetic disk, a static RAM (SRAM), a dynamic RAM (DRAM), a read only memory (ROM), or the like. Generally, the database device 200 may include various storage devices capable of serving as storage processors.

The output processor 400 may output a value learned by the machine learning processor 300. The output processor 400 may output HIC values with respect to inputs of the first data and the second data generated using a machine learning model by the machine learning processor 300. For example, when a user inputs test target data of a vehicle, i.e., a target for testing and evaluating a driver impact amount, to the machine learning processor 300, the output processor 400 may output a predicted HIC value with respect to the test target data.

A controller 500 may be implemented as a memory, which stores an algorithm for controlling operations of various components disposed in the vehicle or data on a program reproducing the algorithm, and a processor configured to perform the above-described operations using the data stored in the memory. The memory and the processor may be implemented as separate chips. Alternatively, the memory and the processor may be implemented as a single chip. For example, the controller 500 may include at least one of an electronic control unit (ECU), a central processing unit (CPU), a microprocessor unit (MPU), a micro controller unit (MCU), an application processor (AP), or any type of processor known in the art. In some embodiments, the controller 500 may be formed of a combination of software and hardware capable of performing an operation on at least one application or program for executing a method according to embodiments of the present disclosure.

The existing design data may be a design image of a cross-section of a vehicle, and the image may be generated by cropping an outer portion of the image of the existing design data. The existing design data may include material information of the headlining. The material information may be information in which a material of the headlining is reflected in the design image by at least one of a color, a chroma, a brightness, a solid line, and a dotted line. In an embodiment, for the purpose of the driver impact amount prediction, a roof, a pillar, an airbag, and a steering wheel, which are interior structures of the vehicle, may be distinguished from one another by color.

In some embodiments, an image output generated based on the existing design data may be expressed by using various colors, where the color may reflect the material information of the headlining. For example, a headform material may be red, a metal material may be blue, a plastic material may be green, and a soft material may be light blue. The headlining is made of various materials, and resistance with respect to the impact varies depending on the material. In order to reflect the above information, the existing design data may include color information that reflects the material information of the headlining. In some embodiments, the material information may be expressed by using not only color but also a chroma, a brightness, a solid line, and a dotted line such that the materials of the headlining may be distinguished from one another.

The image may be an image obtained by cropping an outer portion of a design image corresponding to the existing design data by the same size on the basis of the headform. The image may also be obtained by enlarging a blank image region excluding the design image with respect to the existing design data.

For example, an blank image region may be added to a portion of the image to prevent loss of an image to be output. In other words, when design images corresponding to the existing design data share the same impact point by adding the blank image region, the blank image region of the design image is not relevant, and each image may be cropped to the same size.

The image may be extracted on the basis of the headform included in the existing design data. According to one embodiment, when it is determined that a portion of a partial image set on the basis of the headform is out of the entire image of the existing design data, the data processing processor 100 may extend a blank region of the entire image.

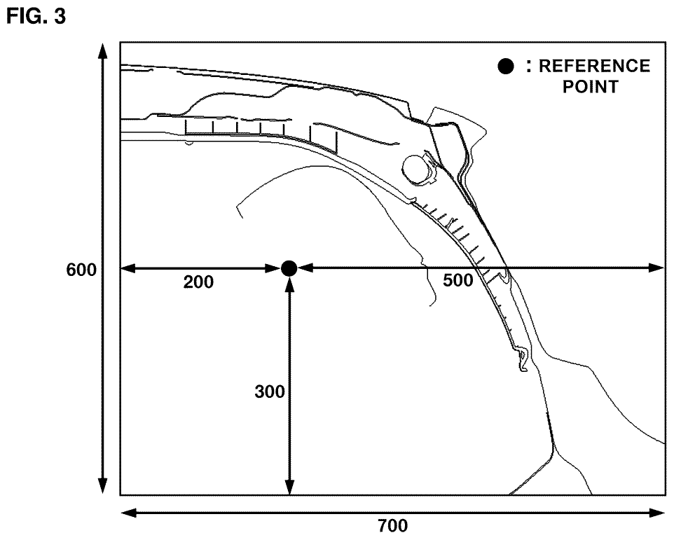

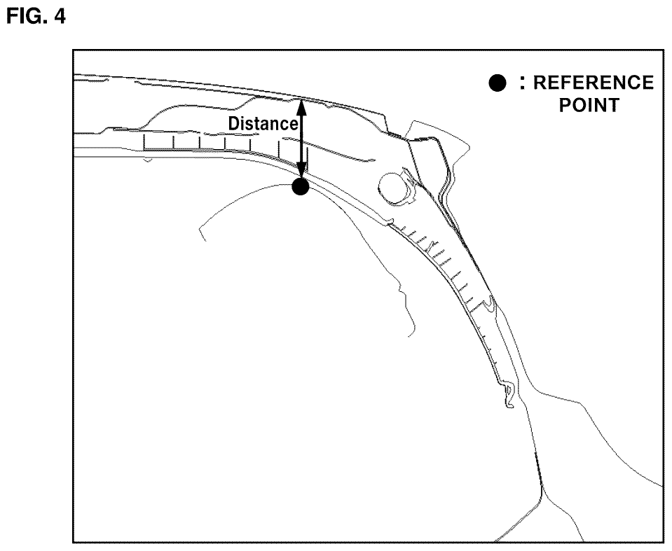

FIGS. 3 and 4 are diagrams for describing pre-processing performed by an FMH impact performance prediction device using artificial intelligence, according to an embodiment of the present disclosure.

Referring to FIG. 3, pre-processing for generating the pre-processed test target image may be performed by setting image sizes the same on the basis of a headroom center of the vehicle input for the machine learning. As one example, as shown in FIG. 3, the pre-processing may specify a pixel-based size based on an H axis in a drawing of the CATIA and adjust a size of the image input to the machine learning processor 300 to a size of 600*700. As an example, a reference point of FIG. 3 may be set based on a headform of a dummy, such as a center of the headroom of the vehicle.

Referring to FIG. 4, pre-processing process for generating the pre-processed test target distance value may extract and use a vertical distance (in units of pixels) between a collision point of the headform and a vehicle body. For example, pre-processing process for generating the pre-processed test target distance value may extract and use a vertical distance between the collision point of the headform and the roof.

The pre-processed test target image and the pre-processed test target distance value may thus be generated as result values of the pre-processing.

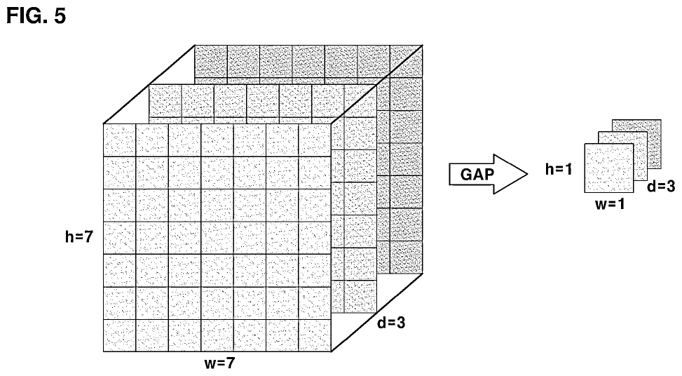

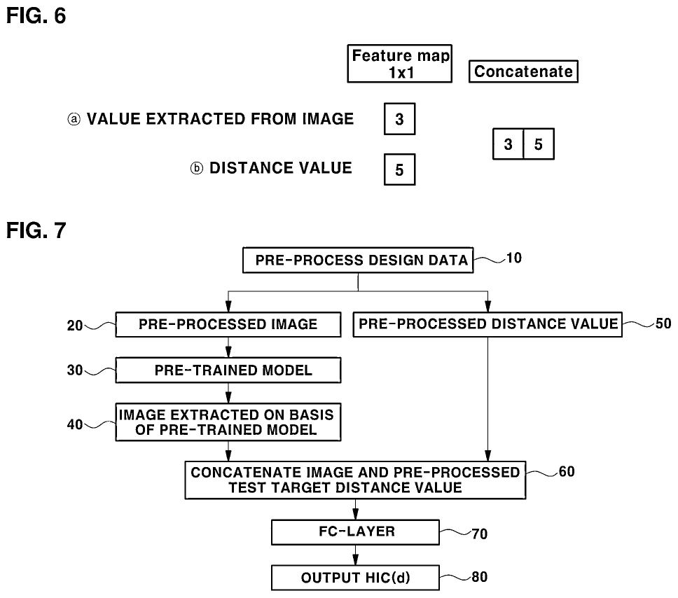

FIG. 5 is a diagram for describing states before and after GAP performed by an FMH impact performance prediction device using artificial intelligence, according to an embodiment of the present disclosure. FIG. 6 is a diagram for describing a concatenation method of an FMH impact performance prediction device using artificial intelligence, according to an embodiment of the present disclosure.

Referring to FIG. 5, the image generated by extraction using the pre-trained model may be generated further using GAP. As an example, in an embodiment in which the pre-processed test target image is a three channel red green blue (RGB) image, a depth d may be 3, a size of the feature map output by DenseNet201 may be 7×7, and after the GAP, the dimension of 7×7×3 may be reduced to a dimension of 1×1×3.

Referring to FIG. 6, as an example, with two feature maps, each having a size of 1×1 and respectively having depth values of 3 and 5, machine learning may be performed by concatenating the two feature maps. More specifically, the first data may be a 1×1 feature map obtained by performing the GAP on the 7×7 feature map extracted using the pre-trained model (e.g., DenseNet201), and the second data may be a distance value of 1×1. The first data and the second data may be concatenated for use as input values of the FC Layer.

FIG. 7 is a flowchart for describing an FMH impact performance prediction method using artificial intelligence, according to an embodiment of the present disclosure.

Referring to FIG. 7, in the FMH impact performance prediction method using artificial intelligence according to an embodiment of the present disclosure, a pre-processed image (20) and a pre-processed distance value (50) may be obtained through pre-processing of existing design data (10). An image may be generated by extracting a pre-processed test target image, generated by pre-processing test target design data, using a pre-trained model. For example, in generating a pre-processed test target distance value by pre-processing the test target design data, a pre-processed image may be extracted using a DenseNet201 model which is the pre-trained model (30), and the image may be generated by extraction on the basis of the pre-trained model learned using GAP (40).

The image generated by extraction using the pre-trained model and the pre-processed test target distance value may be concatenated (60). Impact performance, in which parameters of a neural network are updated by learning based on the image obtained by pre-processing existing design data and existing impact amount data corresponding to the existing design data may be predicted (70). In outputting a predicted impact performance value, an HIC value may be output (80).

The HIC value may be output as an image in the form of a color map and may include an actual HIC absolute value, a predicted HIC absolute value, an actual HIC level value, a predicted HIC level value, and information on a probability of predicting a corresponding level.

In summary, the present disclosure relates to an FMH impact performance prediction device and a method based on a machine learning model, and provides an impact performance prediction device and a method that are capable of performing machine learning by concatenating first data and second data that are input to the machine learning and output the HIC values, thereby deriving an objective result with the same evaluation model.

The present disclosure can obtain the following effects according to a combination of the above-described embodiments and a configuration, which is described below, and a use relationship.

In contrast to the existing analysis-based performance prediction process, there is an effect of reducing a prediction error and costs and man-hours through deep learning analysis.

In addition, there is an effect being capable of predicting occupant impact performance of a vehicle when an analysis model in an initial stage of a vehicle design and an actual vehicle test are not possible.

In addition, various effects ascertained directly or indirectly through the present disclosure may be provided.

Hereinabove, although the present disclosure has been described with reference to example embodiments and the accompanying drawings, the present disclosure is not limited thereto, but may be variously modified and altered by those having ordinary skill in the art to which the present disclosure pertains without departing from the spirit and scope of the present disclosure.

Therefore, embodiments of the present disclosure are provided for illustrative purposes and are not intended to limit the technical spirit of the present disclosure. The scope of the present disclosure should be construed on the basis of the accompanying claims, and all the technical ideas within the scope equivalent to the claims should be included in the scope of the present disclosure.

What is claimed is:

1. A free motion headform (FMH) impact performance prediction device using artificial intelligence, the FMH impact performance prediction device comprising:
a data processing processor configured to:
generate an image by extracting a pre-processed test target image, generated by pre-processing test target design data, using a pre-trained model, and
generate a pre-processed test target distance value by pre-processing the test target design data;
a machine learning processor configured to:
concatenate i) the image generated by extraction using the pre-trained model and ii) the pre-processed test target distance value, and
predict impact performance using a neural network in which parameters are updated by learning based on i) an image obtained by pre-processing existing design data and ii) existing impact amount data corresponding to the existing design data; and
an output processor configured to output a value predicted by the machine learning processor.

2. The FMH impact performance prediction device of claim 1, wherein:
the pre-trained model includes a DenseNet201 model, and
the image generated by extraction using the pre-trained model is generated further using global average pooling (GAP).

3. The FMH impact performance prediction device of claim 1, wherein:
the existing design data is a design image of a cross-section of a vehicle, and
generating the image includes cropping an outer portion of the image of the existing design data.

4. The FMH impact performance prediction device of claim 3, wherein the existing design data includes material information on a headlining, wherein the material information reflects a material of the headlining in the design image by at least one among a color, a chroma, a brightness, a solid line, and a dotted line.

5. The FMH impact performance prediction device of claim 3, wherein the image obtained by pre-processing existing design data is obtained by cropping an outer portion of the design image corresponding to the existing design data by a same size on the basis of a headform.

6. The FMH impact performance prediction device of claim 5, wherein the image obtained by pre-processing existing design data is an image in which a blank image region excluding the design image is enlarged with respect to the existing design data.

7. The FMH impact performance prediction device of claim 1, wherein the impact performance prediction is learned by a multi-layer perceptron (MLP) learning model or a convolution neural network (CNN) learning model.

8. A method of predicting free motion headform (FMH) impact performance using artificial intelligence, the method comprising:
generating an image by extracting a pre-processed test target image, generated by pre-processing test target design data, using a pre-trained model;
generating a pre-processed test target distance value by pre-processing the test target design data;
concatenating i) the image generated by extraction using the pre-trained model and ii) the pre-processed test target distance value;
predicting impact performance using a neural network in which parameters are updated by learning based on i) an image obtained by preprocessing existing design data and ii) existing impact amount data corresponding to the existing design data; and
outputting a predicted impact performance value.

9. The method of claim 8, wherein:
the pre-trained model comprises a DenseNet201 model, and
the image generated by extraction using the pre-trained model is generated further using global average pooling (GAP).

10. The method of claim 8, wherein the existing design data is a design image of a cross-section of a vehicle, and wherein the image is generated by cropping an outer portion of the image of the existing design data.

11. The method of claim 10, wherein the existing design data includes material information on a headlining, wherein the material information is information in which a material of the headlining is reflected into the design image by at least one among a color, a chroma, a brightness, a solid line, and a dotted line.

12. The method of claim 10, wherein the image obtained by pre-processing existing design data is obtained by cropping an outer portion of the design image corresponding to the existing design data by a same size on the basis of a headform.

13. The method of claim 12, wherein the image obtained by pre-processing existing design data is an image in which a blank image region excluding the design image is enlarged with respect to the existing design data.

14. The method of claim 8, wherein the impact performance prediction is learned by a multi-layer perceptron (MLP) learning model or a convolution neural network (CNN) learning model.
